(19) United States
(12) Patent Application Publication
(10) Pub. No.: US 2013/0112976 A1
(43) Pub. Date: May 9, 2013

(54) THIN-FILM TRANSISTOR ARRAY SUBSTRATE, ORGANIC LIGHT-EMITTING DISPLAY INCLUDING THE SAME, AND METHOD OF MANUFACTURING THE SAME

(71) Applicants: Byoung-Ki Kim, Yongin-city (KR); Dae-Woo Lee, Yongin-city (KR); Jong-Hyun Choi, Yongin-city (KR)

(72) Inventors: Byoung-Ki Kim, Yongin-city (KR); Dae-Woo Lee, Yongin-city (KR); Jong-Hyun Choi, Yongin-city (KR)

(73) Assignee: Samsung Mobile Display Co., Ltd., Yongin-city (KR)

(21) Appl. No.: 13/526,257

(22) Filed: Jun. 18, 2012

(30) Foreign Application Priority Data
Nov. 8, 2011 (KR) 10-2011-0115924

(51) Int. Cl. H01L 29/786; H01L 21/336

(52) U.S. Cl. 257/59; 257/57; 257/66; 257/72; 438/239; 257/E29.273; 257/E21.411

(57) ABSTRACT

A thin-film transistor array substrate is disclosed. In one embodiment, the substrate includes: i) a thin-film transistor including an active layer, and gate, source and drain electrodes, ii) a lower electrode of a capacitor, iii) an upper electrode of the capacitor formed on the lower electrode iv) a first insulation layer between the lower and upper electrodes, and between the active layer and the gate electrode, and having a gap outside the lower electrode. The substrate may further include i) a second insulation layer formed on the first insulation layer and having the same etching surface as the first insulation layer in the gap, ii) a bridge formed of the same material as the source and drain electrodes, and filling a part of the gap and iii) a third insulation layer covering the source and drain electrodes and exposing a pixel electrode.

### CROSS-REFERENCE TO RELATED PATENT APPLICATION

This application claims the benefit of Korean Patent Application No. 10-2011-0115924, filed on Nov. 8, 2011, in the Korean Intellectual Property Office, the disclosure of which is incorporated herein in its entirety by reference.

### BACKGROUND

1. Field

The described technology generally relates to a thin-film transistor array substrate, an organic light-emitting display including the same, and a method of manufacturing the thin-film transistor array substrate.

2. Description of the Related Technology

A flat panel display, such as an organic light-emitting display and a liquid crystal display, generally includes many pixel circuits which each include a thin-film transistor (TFT), a capacitor, and wires connecting the TFT and the capacitor.

The flat panel display is usually manufactured by forming a minute pattern of a TFT, a capacitor, and wires on a substrate via a photolithography process that transfers the minute pattern by using a mask.

### SUMMARY

One inventive aspect is a thin-film transistor array substrate having simple manufacturing processes and excellent signal transmission, an organic light-emitting display including the same, and a method of manufacturing the same.

Another aspect is a thin-film transistor array substrate which includes: a thin-film transistor comprising an active layer, a gate electrode, a source electrode, and a drain electrode; a lower electrode of a capacitor formed from the same layer as the active layer; an upper electrode of the capacitor formed on the lower electrode; a first insulation layer between the lower and upper electrodes, and between the active layer and the gate electrode, and having a gap outside the lower electrode; a second insulation layer formed on the first insulation layer and having the same etching surface as the first insulation layer in the gap; a bridge formed of the same material as the source and drain electrodes, and filling a part of the gap; a pixel electrode formed of the same material as the upper electrode; and a third insulation layer covering the source and drain electrodes and exposing the pixel electrode.

The active layer and the lower electrode may comprise an ion impurity-doped semiconductor material.

The upper electrode and the pixel electrode may comprise a transparent conductive material.

The transparent conductive material may comprise at least one selected from the group consisting of an indium tin oxide (ITO), an indium zinc oxide (IZO), a zinc oxide (ZnO), an indium oxide (In2O3), an indium gallium oxide (IGO), and an aluminum zinc oxide (AZO).

The thin-film transistor array substrate may further comprise a first connector connected to the lower electrode; and a second connector connected to the upper electrode, wherein a first portion of the gap is formed between the lower electrode and the first connector, and a second portion of the gap is formed in the first insulation layer formed outside the lower electrode.

The bridge may be formed in the second portion of the gap.

The first connector may comprise the same material as the lower electrode.

The second connector may comprise the same material as the upper electrode.

The second connector may be formed on and connected to the bridge formed in the second portion of the gap and the second insulation layer.

The thin-film transistor array substrate may further comprise a wire formed of the same material as the source and drain electrodes between the second connector and the second insulation layer, and directly contacting the second connector.

A protection film may be further formed in the first portion of the gap.

The protection film may be formed of the same material as the source and drain electrodes.

The protection film may be formed of the same material as the upper electrode.

The protection film may be insulated from the upper electrode.

The third insulation layer may contact the upper electrode.

Another aspect is an organic light-emitting display which includes: a thin-film transistor comprising an active layer, a gate electrode, a source electrode, and a drain electrode; a lower electrode of a capacitor formed from the same layer as the active layer; an upper electrode of the capacitor formed on the lower electrode; a first insulation layer between the lower and upper electrodes, and between the active layer and the gate electrode, and having a gap outside the lower electrode; a second insulation layer formed on the first insulation layer and having the same etching surface as the first insulation layer; a bridge formed of the same material as the source and drain electrodes, and filling a part of the gap; a pixel electrode formed of the same material as the upper electrode; a third insulation layer covering the source and drain electrodes and exposing the pixel electrode; an organic light-emitting layer on the pixel electrode; and a counter electrode on the organic light-emitting layer.

The counter electrode may be a reflective electrode reflecting light emitted from the organic light-emitting layer.

The pixel electrode may comprise a transparent conductive material.

The pixel electrode may further comprise a semi-transmission layer comprising a semi-transmission material.

Another aspect is a method of manufacturing a thin-film transistor array substrate which includes: performing a first mask process by forming a semiconductor layer on a substrate and forming an active layer of a thin-film transistor and a lower electrode of a capacitor by patterning the semiconductor layer; performing a second mask process by forming a first insulation layer, forming a first metal layer on the first insulation layer, and forming an etch stop layer corresponding to the lower electrode and a gate electrode corresponding to a part of the active layer by patterning the first metal layer; performing a third mask process by forming a second insulation layer, and etching the first and second insulation layer such that a gap exposing the etch stop layer and an opening exposing a part of the active layer are formed; performing a fourth mask process by forming a second metal layer, and forming a bridge filing a part of the gap and source and drain electrodes filling the opening of the active layer by patterning the second metal layer; performing a fifth mask process by forming a third metal layer, and forming a pixel electrode and an upper electrode of the capacitor by patterning the third metal layer; and performing a sixth mask process by forming a third insulation layer, and forming an opening exposing the pixel electrode.

The method may further comprise doping an ion impurity after performing the second mask process.

The etch stop layer may be removed while performing the third mask process.

The method may further comprise doping an ion impurity after performing the fourth mask process.

A first connector connected to the lower electrode may be simultaneously formed by patterning the semiconductor layer while performing the first mask process.

A first portion of the gap may be formed between the lower electrode and the first connector, and a second portion of the gap may be formed in the first insulation layer formed outside the lower electrode while performing the third mask process.

The bridge may be formed in the second portion of the gap while performing the fourth mask process.

A second connector connected to the upper electrode may be simultaneously formed by patterning the third metal layer, wherein the second connector is formed on the bridge, while performing the fifth mask process.

A protection film may be further formed in the first portion of the gap by using the second metal layer while performing the fourth mask process.

A protection film may be further formed in the first portion of the gap by using the third metal layer while performing the fifth mask process.

### BRIEF DESCRIPTION OF THE DRAWINGS

FIG. 1 is a cross-sectional view schematically illustrating an organic light-emitting display according to an embodiment.

FIG. 2 is a plan view schematically illustrating a capacitor region of an organic light-emitting display according to an embodiment.

FIGS. 3A through 3F are views schematically illustrating results of mask processes of the organic light-emitting display of FIG. 1.

FIG. 4 is a cross-sectional view schematically illustrating an organic light-emitting display according to another embodiment.

FIG. 5 is a cross-sectional view schematically illustrating an organic light-emitting display according to another embodiment.

FIGS. 6A through 6E are cross-sectional views for describing a method of manufacturing an organic light-emitting display according to a first comparative example.

FIGS. 7A through 7C are cross-sectional views for describing a method of manufacturing an organic light-emitting display according to a second comparative example.

### DETAILED DESCRIPTION

According to a photolithography process, photoresist is uniformly coated on a substrate on which the minute pattern is to be formed, is exposed to light by using an exposure device, such as a stepper, and then the exposed photoresist (when the photoresist is positive photoresist) is developed. After developing the photoresist, the remaining photoresist is used to etch the minute pattern on the substrate, and the photoresist is removed after forming the minute pattern.

As described above, since a mask having a pattern is first prepared in the step of transferring a pattern by using the mask, manufacturing costs for preparing the mask are increased as the number of processes using the mask increases. Also, since the above complex operations are performed, manufacturing processes are complex, a manufacturing time is increased, and manufacturing costs are increased due to the increased manufacturing time.

Hereinafter, embodiments will be described with reference to accompanying drawings. As used herein, the term “and/or” includes any and all combinations of one or more of the associated listed items.

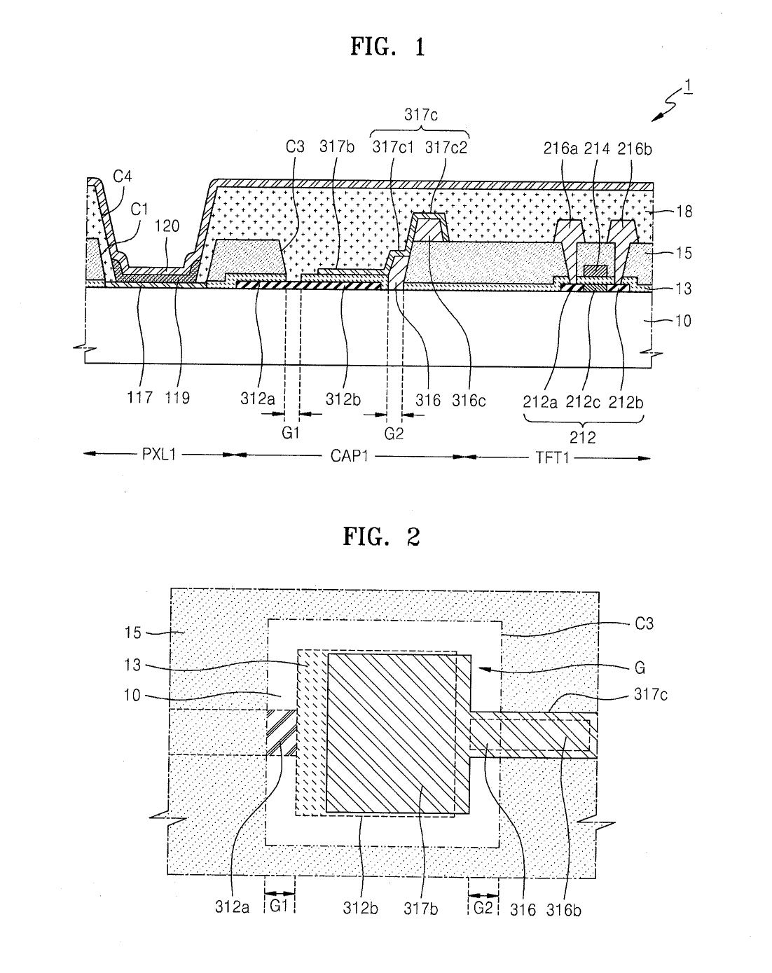

FIG. 1 is a cross-sectional view schematically illustrating an organic light-emitting display 1 according to an embodiment.

Referring to FIG. 1, the organic light-emitting display 1 according to the current embodiment includes a pixel region PXL1, a transistor region TFT1, and a capacitor region CAP1 on a substrate 10.

In the transistor region TFT1, an active layer 212 of a thin-film transistor is formed on the substrate 10. The active layer 212 may be formed of a semiconductor including amorphous silicon or polysilicon. The active layer 212 may include a channel region 212c and source and drain regions 212a and 212b doped with ion impurities and that are outside the channel region 212c. Although not illustrated in FIG. 1, a buffer layer (not shown) including silicon oxide (SiO2) and/or silicon nitride (SiNx) may be further formed between the substrate 10 and the active layer 212 for evenness of the substrate 10 and to prevent impure elements from penetrating into the substrate 10.

A gate electrode 214 is formed on the active layer 212 at a location corresponding to the channel region 212c of the active layer 212, wherein a first insulation layer 13 constituting a gate insulation film is formed between the gate electrode 214 and the active layer 212.

A source electrode 216a and a drain electrode 216b that are connected to the source region 212a and the drain region 212b of the active layer 212, respectively, are formed on the gate electrode 214. Furthermore, a second insulation layer 15 constituting an interlayer insulation film is formed between the gate electrode 214 and the source and drain electrodes 216a and 216b. Although not illustrated in FIG. 1, a layer including the same transparent conductive material as a pixel electrode 117 that is described below may be further formed on the source and drain electrodes 216a and 216b.

A third insulation layer 18 is formed on the second insulation layer 15 to cover the source and drain electrodes 216a and 216b. The third insulation layer 18 may include an organic insulation film or both of an inorganic insulation film and an organic insulation film stacked on each other. Examples of the organic insulation film forming the third insulation layer 18 include general-purpose polymers, such as polymethyl methacrylate (PMMA) and polystyrene (PS), polymer derivatives having a phenol group, acryl-based polymers, imide-based polymers, arylether-based polymers, amide-based polymers, fluorine-based polymers, p-xylene-based polymers, vinyl alcohol-based polymers, and blends thereof.

In the pixel region PXL1, the pixel electrode 117 is formed on the substrate 10 in an opening C1 formed in the first and second insulation layers 13 and 15. The pixel electrode 117 may be formed of the same material as an upper electrode 317b of a capacitor that is described below.

The pixel electrode 117 may be formed of a transparent conductive material so that light passes through the pixel electrode 117. The transparent conductive material may be at least one selected from the group consisting of indium tin oxide (ITO), indium zinc oxide (IZO), zinc oxide (ZnO), indium oxide (In2O3), indium gallium oxide (IGO), and aluminum zinc oxide (AZO). Although not illustrated in FIG. 1, a buffer layer (not shown) may be further formed between the substrate 10 and the pixel electrode 117.

An organic light-emitting layer 119 is formed on the pixel electrode 117. The organic light-emitting layer 119 may be formed in an opening C4 of the third insulation layer 18. Light emitted from the organic light-emitting layer 119 may be emitted toward the substrate 10 through the pixel electrode 117 formed of the transparent conductive material.

The organic light-emitting layer 119 may be formed of a low molecular organic material or a high molecular organic material. If the organic light-emitting layer 119 is formed of a low molecular organic material, a hole transport layer (HTL), a hole injection layer (HIL), an electron transport layer (ETL), and an electron injection layer (EIL) may be stacked on each other with respect to the organic light-emitting layer 119. Also, other layers may be stacked if required. Here, examples of the low molecular organic material include copper phthalocyanine (CuPc), N′-di (naphthalene-1-yl)-N, N′-diphenyl-benzidine (NPB), and tris-8-hydroxyquinoline aluminum (Alq3). Alternatively, if the organic light-emitting layer 119 is formed of a high molecular organic material, an HTL may be included as well as the organic light-emitting layer 119. The HTL may be formed of poly-(3,4)-ethylene-dihydroxy thiophene (PEDOT) or polyaniline (PANT). Here, examples of the high molecular organic material include polyphenylene vinylene (PPV) and polyfluorene.

A counter electrode 120 constituting a common electrode is formed on the organic light-emitting layer 119. In the organic light-emitting display 1 according to the current embodiment, the pixel electrode 117 may be used as an anode and the counter electrode 120 is used as a cathode, but polarities thereof may be opposite.

The counter electrode 120 may be a reflective electrode including a reflective material. Here, the counter electrode 120 may include at least one material from among Al, Mg, Li, Ca, LiF/Ca, and LiF/Al. When the counter electrode 120 is a reflective electrode, light emitted from the organic light-emitting layer 119 may be reflected at the counter electrode 120, penetrate through the pixel electrode 117 formed of a transparent conductive material, and emitted toward the substrate 10.

Although not illustrated in FIG. 1, the pixel electrode 117 may further include a semi-transmission metal layer (not shown) including a semi-transmission material. When the pixel electrode 117 further includes the semi-transmission metal layer, the counter electrode 120 constituting the reflective electrode operates as a reflection mirror and the semi-transmission metal layer operates as a semi-transmission mirror. Thus, the light emitted from the organic light-emitting layer 119 may resonate between the counter electrode 120 and the semi-transmission metal layer, thereby increasing light extraction efficiency.

The semi-transmission metal layer may be formed of at least one of the following: silver (Ag), an Ag alloy, aluminum (Al), and an Al alloy. The thickness of the semi-transmission metal layer may be below or substantially equal to about 300 □ so as to operate as a resonance mirror with the counter electrode 120 constituting the reflective electrode.

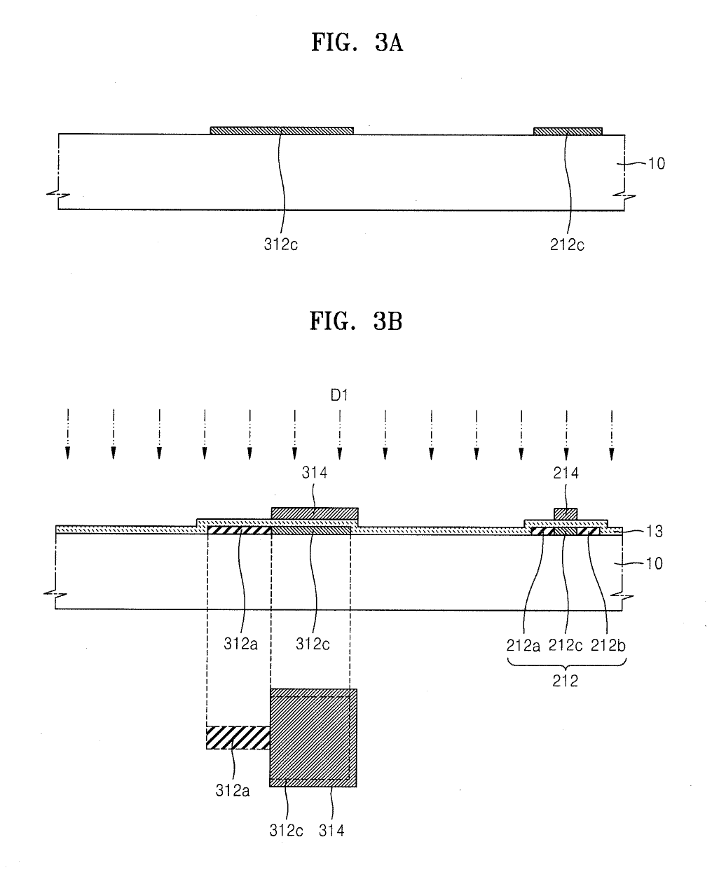

FIG. 2 is a plan view schematically illustrating the capacitor region CAP1 of the organic light-emitting display 1, according to an embodiment. The capacitor region CAP1 of FIG. 2 includes a lower electrode 312b, the upper electrode 317b, the first insulation layer 13, and the second insulation layer 15.

Referring to FIGS. 1 and 2, the capacitor region CAP1 includes the lower electrode 312b of the capacitor and a first connector 312a connected to the lower electrode 312b on the substrate 10.

The lower electrode 312b may be from the same layer as the active layer 212.

The lower electrode 312b may include an ion impurity-doped semiconductor that is the same material as the source and drain regions 212a and 212b of the active layer 212. The first connector 312a that transmits a signal (current/voltage) to the lower electrode 312b may be formed of the same material layer as the lower electrode 312b. Thus, the first connector 312a may include an ion impurity-doped semiconductor, similar to the lower electrode 312b.

The upper electrode 317b of the capacitor and a second connector 317c connected to the upper electrode 317b are formed on the lower electrode 312b.

The upper electrode 317b may be formed of the same material as the pixel electrode 117 described above. The second connector 317c that transmits a signal to the upper electrode 317b may be formed of the same material as the upper electrode 317b. The second connector 317c may include a first portion 317c1 formed on a bridge 316 described below and a second portion 317c2 formed on a wire 316c formed on the second insulation layer 15 and formed of the same material as the source and drain electrodes 216a and 216b. Since the second connector 317c is electrically connected to the upper electrode 317b, the first and second portions 317c1 and 317c2 are not short-circuited.

The first insulation layer 13 operating as a gate insulation film may extend from the transistor region TFT1 and be formed between the lower and upper electrodes 312b and 317b of the capacitor to operate as a dielectric film. A portion where the first insulation layer 13 is not formed exists outside the lower electrode 312b in the capacitor region CAP1. In other words, the first insulation layer 13 has a predetermined gap G (refer to FIG. 2) in the capacitor region CAP1. The gap G is formed since the first insulation layer 13 is etched while etching the second insulation layer 15. In one embodiment, a first portion G1 of the gap G is formed in the first insulation layer 13 between the lower electrode 312b and the first connector 312a, and a second portion G2 of the gap G is formed in the first insulation layer 13 formed outside the lower electrode 312b.

The second insulation layer 15 extending from the transistor region TFT1 is formed on the first insulation layer 13. The second insulation layer 15 has an opening C3 larger than that of the upper electrode 317b. As described below, since a semiconductor layer forming the lower electrode 312b and the first connector 312a is doped with ion impurities throughout via the opening C3, signal transmission efficiency of the capacitor is improved. The opening C3 has the same etching surface as the first insulation layer 13 in the gap G.

The bridge 316 formed of the same material as the source and drain electrodes 216a and 216b is included in a part of the gap G. The bridge 316 is formed in the second portion G2 of the gap G. As described above, since the second connector 317c is electrically connected to the upper electrode 317b, the first and second portions 317c1 and 317c2 forming the second connector 317c are not short-circuited. If the bridge 316 is not formed in the second portion G2 of the gap G, the second connector 317c is connected to the upper electrode 317b in the second portion G2 along the etching surfaces of the first and second insulation layers 13 and 15 having a high stepped difference, and thus, the first and second portions 317c and 317c2 may be short-circuited. Thus, such short circuit may be prevented by forming the bridge 316 in the second portion G2 of the gap G.

The second connector 317c may be formed of a transparent conductive material, similar to the upper electrode 317b. If the resistance of the transparent conductive material is high, the wire 316c connected to the upper electrode 317b through the second connector 317c may be a metal wire formed of a low resistance material. In the current embodiment, the wire 316c is formed of the same material layer as the source and drain electrodes 216a and 216b. Here, the second portion 317c2 of the second connector 317c may be formed on the wire 316c. A risk of a short circuit may be further increased since the second connector 317c is connected to the upper electrode 317b along not only the etching surfaces of the first and second insulation layers 13 and 15 formed in the second portion G2 but also an etching surface of the wire 316c. However, the bridge 316 may prevent the short circuit of the second connector 317c.

The third insulation layer 18 is formed on the second insulation layer 15. As described above, the third insulation layer 18 may include an organic insulation film or both of an inorganic insulation film and an organic insulation film stacked on each other. By disposing the third insulation layer 18, including an organic insulation material having a low dielectric constant, between the counter electrode 120 and the upper electrode 317b, parasitic capacitance formed between the counter electrode 120 and the upper electrode 317b is reduced, thereby preventing signal interference due to the parasitic capacity.

The first and second connectors 312a and 317c are shown as if they are disposed in opposite directions in FIGS. 1 and 2, but locations of the two connectors 312a and 317c are not limited thereto. A connecting direction of the first and second connectors 312a and 317c are not limited as long as the connectors 312a and 317c are connected to the lower and upper electrodes 312b and 317b, respectively.

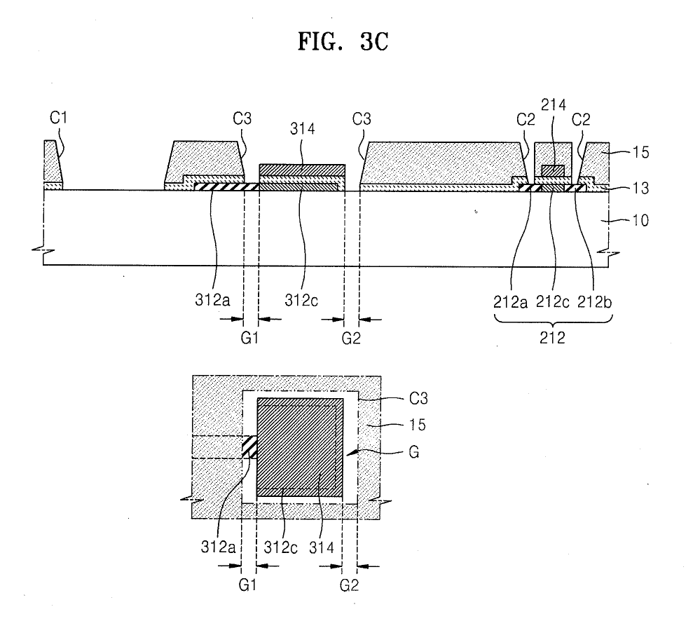

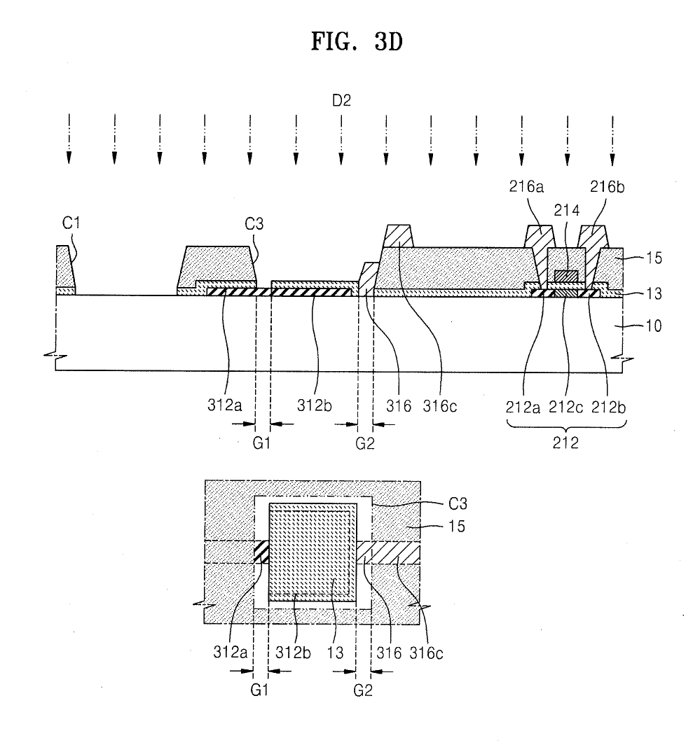

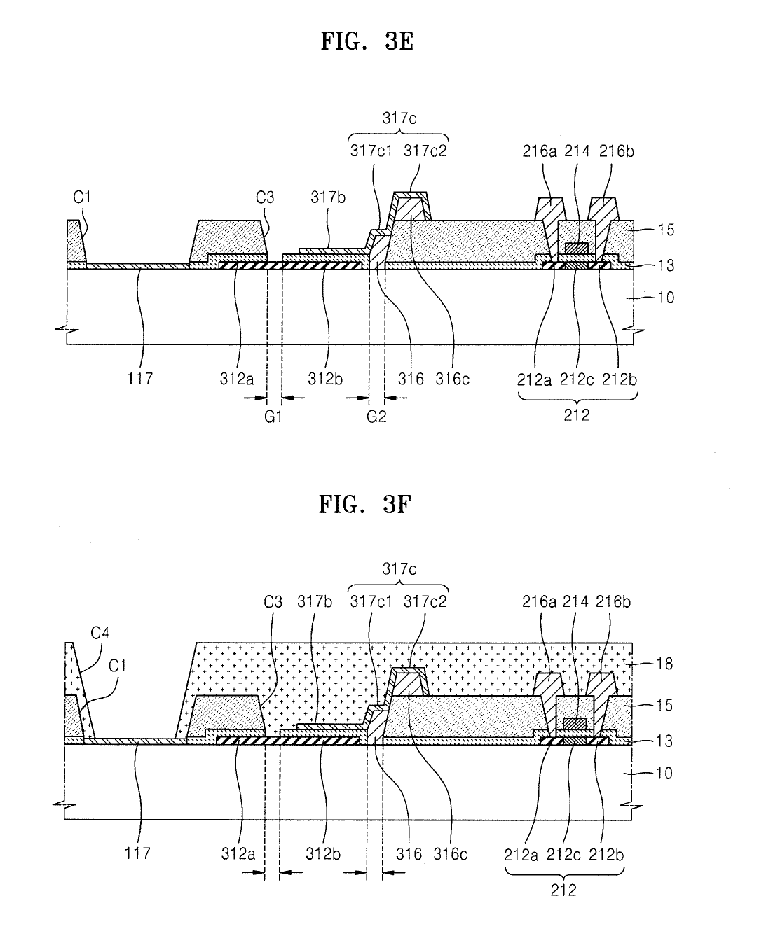

FIGS. 3A through 3F are views schematically illustrating results of mask processes of the organic light-emitting display 1 of FIG. 1.

FIG. 3A is a cross-sectional view schematically illustrating a result of a first mask process of the organic light-emitting display 1 according to the current embodiment.

Referring to FIG. 3A, a semiconductor layer is patterned on the substrate 10 to form the channel region 212c not doped with ion impurities, and a layer 312c including a lower electrode and first connector not doped with ion impurities.

Although not shown in FIG. 3A, the semiconductor layer (not shown) is deposited on the substrate 10, photoresist (not shown) is coated on the semiconductor layer, and the semiconductor layer is patterned by a photolithography process using a first photo mask (not shown), thereby forming the channel region 212c and a layer 312c not doped with ion impurities. The first mask process using the photolithography process is performed via a series of processes, such as exposing the first photo mask to light using an exposure device, and then developing, etching, and stripping or ashing the first photo mask.

The semiconductor layer may include amorphous silicon or polysilicon. Here, the polysilicon may be formed by crystallizing amorphous silicon. The amorphous silicon may be crystallized by using any method, such as a rapid thermal annealing (RTA) method, a solid phase crystallization (SPC) method, an excimer laser annealing (ELA) method, a metal-induced crystallization (MIC) method, a metal-induced lateral crystallization (MILC) method, or a sequential lateral solidification (SLS) method.

FIG. 3B is a cross-sectional view schematically illustrating a result of a second mask process of the organic light-emitting display 1, and a plan view schematically illustrating a capacitor region according to the current embodiment.

Referring to FIG. 3B, the first insulation layer 13 is stacked on the result product of the first mask process of FIG. 3A, and a first metal layer (not shown) is stacked on the first insulation layer 13 and then is patterned. As a result of patterning, on the first insulation layer 13, the gate electrode 214 is formed in the transistor region TFT1 and at the same time, an etch stop layer 314 is formed in the capacitor region CAP.

The first insulation layer 13 operates as a gate insulation film of the thin-film transistor and a dielectric film of the capacitor.

The gate electrode 214 and the etch stop layer 314 may be formed of a single layer or layers of at least one low resistance metal selected from the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The ion impurities are first doped (D1) on the structure. B or P-ions may be doped as the ion impurities, and here, the ion impurities may be doped on the active layer 212 and the first connector 312a in concentration substantially equal to or above about 1×10¹⁵ atoms/cm². At this time, the gate electrode 214 functions as a self-aligned mask. As a result, the active layer 212 includes the source and drain regions 212a and 212b, and the channel region 212 therebetween, which are doped with the ion impurities.

Since the etch stop layer 314 operates as a block mask, of the layer 312c not doped with the ion impurities, the lower electrode 312b covered by the etch stop layer 314 is not doped, and the first connector 312a not covered by the etch stop layer 314 is doped.

FIG. 3C is a cross-sectional view schematically illustrating a result of a third mask process of the organic light-emitting display 1, and a plan view schematically illustrating a capacitor region according to the current embodiment.

Referring to FIG. 3C, the second insulation layer 15 is stacked on the result product of the second mask process of FIG. 3B, and the first and second insulation layers 13 and 15 are substantially simultaneously patterned to form the opening C1 exposing a pixel region, an opening C2 exposing parts of the source and drain regions 212a and 212b of the active layer 212, and the opening C3 exposing the entire etch stop layer 314. Here, in the capacitor region, the etch stop layer 314 prevents the first insulation layer 13 below the etch stop layer 314 from being etched.

Since the first and second insulation layers 13 and 15 are etched together in the same mask process, the part of the first insulation layer 13 exposed through the opening C3 is removed to form the gap G in the capacitor region. In the first insulation layer 13, the first portion G1 of the gap G is formed between the layer 312c, which is covered by the etch stop layer 314, and the first connection 312a. In the first insulation layer 13, the second portion G2 of the gap G is formed outside the lower electrode 312b covered by the etch stop layer 314.

FIG. 3D is a cross-sectional view schematically illustrating a result of a fourth mask process of the organic light-emitting display 1, and a plan view schematically illustrating a capacitor region according to the current embodiment.

In FIG. 3D, a second metal layer (not shown) is stacked on the result product of the third mask process of FIG. 3C to fill the openings C1 through C3, and then is patterned. The second metal layer is patterned to form the bridge 316 in the second portion G2, and the source electrode 216a, the drain electrode 216b, and the wire 316c on the second insulation layer 15. Here, the etch stop layer 314 is removed.

The second metal layer may include a single layer or layers formed of at least one of the following: Al, Pt, Pd, Ag, Mg, Au, Ni, Nd, Ir, Cr, Li, Ca, Mo, Ti, W, and Cu. Here, the second metal layer directly contacts the first connector 312a in the first portion G1 of the gap G, and thus, a silicon-metal compound, such as silicide, may be generated. The silicon-metal compound may not be removed and continuously remain.

Such a structure is secondly doped with ion impurities. Since the etch stop layer 314 is removed, the lower electrode 312b is doped with the ion impurities. Thus, since a region not doped with ion impurities does not exist between the lower electrode 312b and the first connector 312a, the signal transmission efficiency of the capacitor may be increased.

FIG. 3E is a cross-sectional view schematically illustrating a result of a fifth mask process of the organic light-emitting display 1 according to the current embodiment.

Referring to FIG. 3E, the pixel electrode 117, the upper electrode 317b, and the second connector 317c are formed on the result product of the fourth mask process of FIG. 3D by using the same material via the same mask process.

The pixel electrode 117 is formed in the opening C1, the upper electrode 317b is formed on the lower electrode 312b, and the second connector 317c is formed on the bridge 316 and the second insulation layer 15.

The first portion 317c1 of the second connector 317c is formed on the bridge 316 in the second portion G2 of the gap G, and the second portion 317c2 of the second connector 317c is formed on the wire 316c on the second insulation layer 15. As described above, since the second connector 317c is electrically connected to the upper electrode 317b, the first and second portions 317c1 and 317c2 forming the second connector 317c are not short-circuited. Thus, the bridge 316 formed in the second portion G2 may prevent the second connector 317c from being short-circuited by reducing a stepped difference between the etching surfaces of the first and second insulation layers 13 and 15.

FIG. 3F is a cross-sectional view schematically illustrating a result of a sixth mask process of the organic light-emitting display 1 according to the current embodiment.

Referring to FIG. 3F, the third insulation layer 18 is stacked on the result product of the fifth mask process of FIG. 3E, and the third insulation layer 18 is patterned to form an opening C4 exposing a portion of the top of the pixel electrode 117.

The opening C4 not only defines a light-emitting region but also increases an interval between an edge of the pixel electrode 117 and the counter electrode 120 of FIG. 1, so as to prevent an electric field from concentrating at the edge of the pixel electrode 117, thereby preventing the pixel electrode 117 and the counter electrode 120 from being short-circuited.

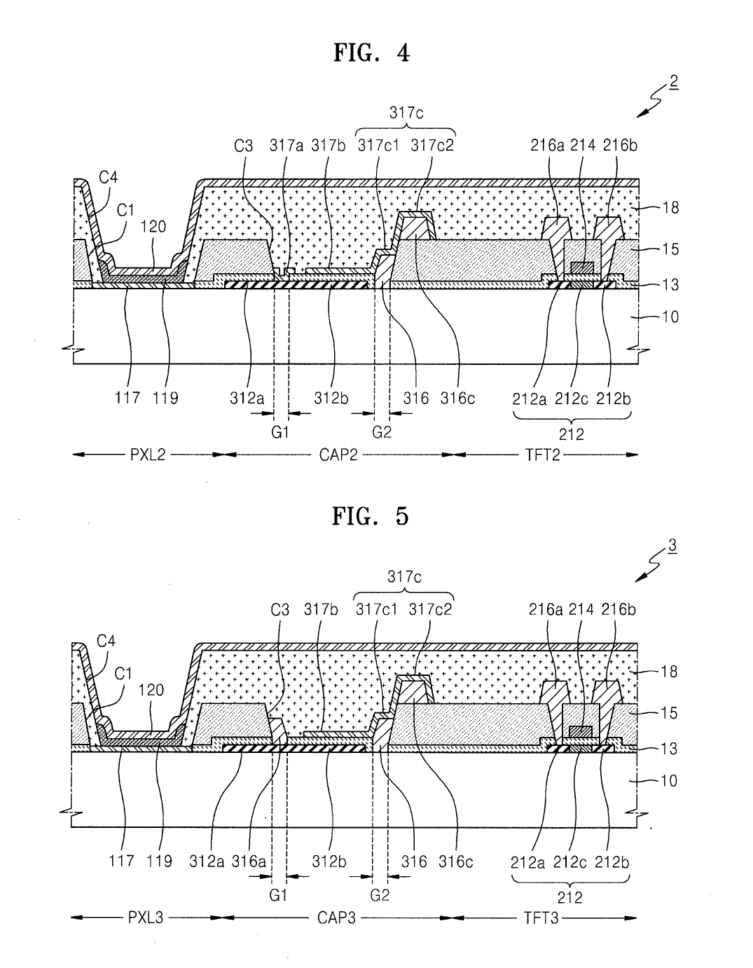

FIG. 4 is a cross-sectional view schematically illustrating an organic light-emitting display 2 according to another embodiment. Hereinafter, only differences between the organic light-emitting displays 1 and 2 are mainly described.

Referring to FIG. 4, the organic light-emitting display 2 according to the current embodiment includes a pixel region PXL2, a transistor region TFT2, and a capacitor region CAP2 on the substrate 10. In the current embodiment, a protection film 317a is further disposed in the first portion G1 of the gap G in the capacitor region CAP2. The protection film 317a is formed of the same material as the upper electrode 317b, and is formed together with the upper electrode 317b in the fifth mask process.

As described above, when the silicon-metal compound, such as silicide, is generated and remains without being completely removed due to the contact of the second metal layer and the first connector 312a in the first portion G1 in the fourth mask process, the lower and upper electrodes 312b and 317b may be short-circuited due to a leakage current. Due to such short circuit, a dark spot may be generated in a corresponding pixel. In the current embodiment, the protection film 317a is formed in the first portion G1 to prevent the short circuit. The protection film 317a is formed together with but insulated from the upper electrode 317b.

FIG. 5 is a cross-sectional view schematically illustrating an organic light-emitting display 3 according to another embodiment. Hereinafter, only differences between the organic light-emitting displays 1 through 3 are mainly described.

Referring to FIG. 5, the organic light-emitting display 3 according to the current embodiment includes a pixel region PXL3, a transistor region TFT3, and a capacitor region CAP3 on the substrate 10. In the current embodiment, a protection film 316a is further disposed in the first portion G1 of the gap G in the capacitor region CAP3. The protection film 316a is formed of the same material as the source and drain electrodes 216a and 216b when the source and drain electrodes 216a and 216b are also formed in the fourth mask process.

As described above, when the silicon-metal compound, such as silicide, is generated and remains without being substantially completely removed due to the contact of the second metal layer and the first connector 312a in the first portion G1 in the fourth mask process, the lower and upper electrodes 312b and 317b may be short-circuited due to a leakage current. Due to such short circuit, a dark spot may be generated in a corresponding pixel. In the current embodiment, the protection film 316a is formed of the same material as the source and drain electrodes 216a and 216b in the first portion G1 to prevent the short circuit.

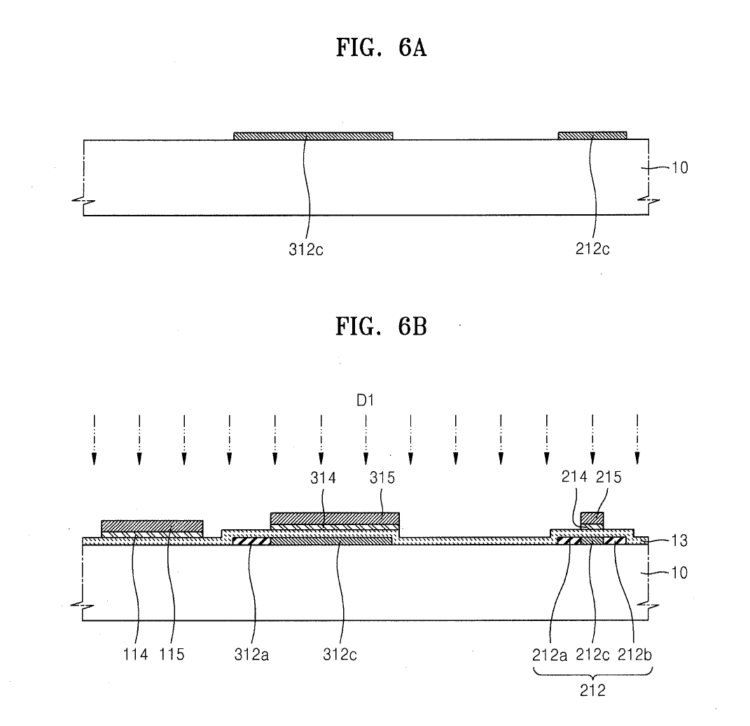

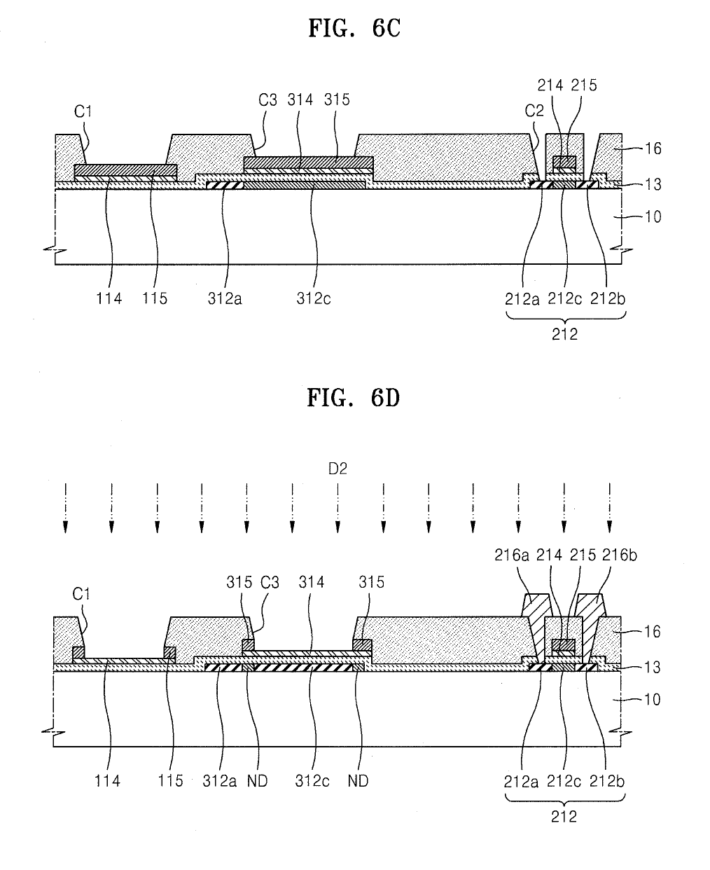

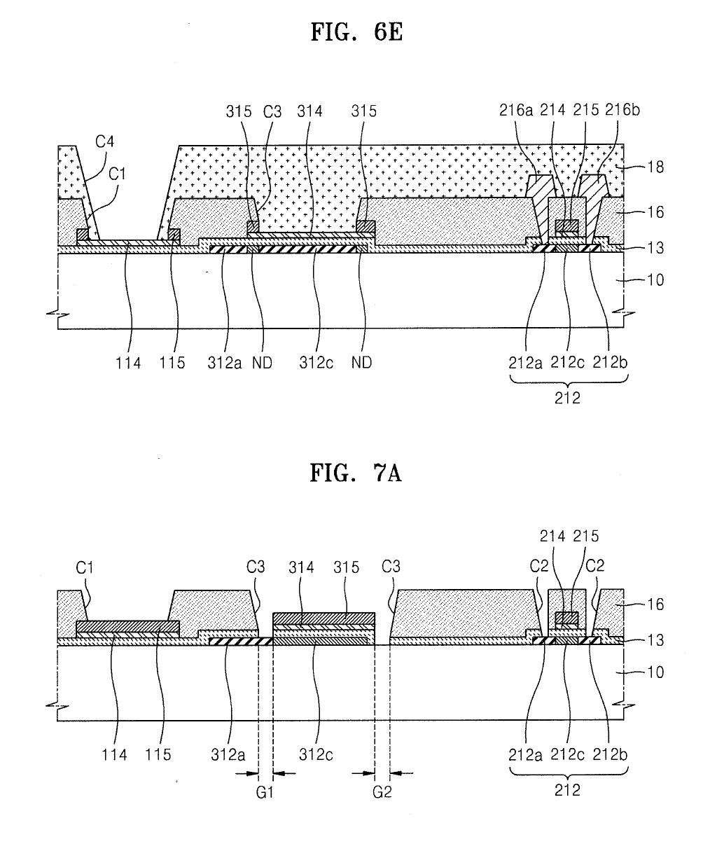

FIGS. 6A through 6E are cross-sectional views for describing a method of manufacturing an organic light-emitting display according to a first comparative example.

Referring to FIG. 6A, the channel region 212c not doped with ion impurities and the layer 312c, including a lower electrode and a first connector not doped with ion impurities, are formed on the substrate 10.

Referring to FIG. 6B, a first metal layer including a transparent conductive material and a second metal layer including a low resistance metal are sequentially stacked on each other and then are patterned to form pixel electrodes 114 and 115, gate electrodes 214 and 215, and upper electrodes 314 and 315, and then first doping (D1) is performed. As a result, the active layer 212 includes the source and drain regions 212a and 212b doped with ion impurities, and the channel region 212c therebetween. Since the upper electrodes 314 and 315 operate as a block mask, the lower electrode 312b of the layer 312, which is covered by the upper electrodes 314 and 315, is not doped with impurities, and the first connector 312a that is not covered is doped.

Referring to FIG. 6C, a second insulation layer 16 is formed, and then the opening C1 exposing a pixel region, the opening C2 exposing parts of the source and drain regions 212a and 212b of the active layer 212, and the opening C3 exposing a portion of the upper electrode 315 are formed. Here, the opening C3 is formed such that the upper electrodes 314 and 315 are not entirely exposed, and only edges of the upper electrodes 314 and 315 are slightly clad.

Referring to FIG. 6D, a second metal layer (not shown) is stacked on the result product of the third mask process of FIG. 6C to fill the openings C1 through C3, and then is patterned to form the source and drain electrodes 216a and 216b. At this time, a portion of the pixel electrode 115 and a portion of the upper electrode 315 are also removed. Here, since the second insulation layer 16 surrounds the edges of the upper electrodes 314 and 315, the edge portion of the upper electrode 315 below the surrounding portion is not removed. Then, second doping (D2) is performed. After the second doping, the lower electrode 312b is doped, but a region ND corresponding to the remaining edge portion of the upper electrode 315 is not doped. Thus, signal quality is decreased as the resistance of the capacitor region is increased.

Referring to FIG. 6E, the third insulation layer 18 is stacked on the result product of the fourth mask process of FIG. 6D, and then is patterned to form the opening C4 exposing the top of the pixel electrode 114.

Thus, according to the first comparative example, the region ND not doped with ion impurities may be formed between the lower electrode 312b and the first connector 312a and increases resistance, thereby decreasing signal transmission efficiency of a capacitor.

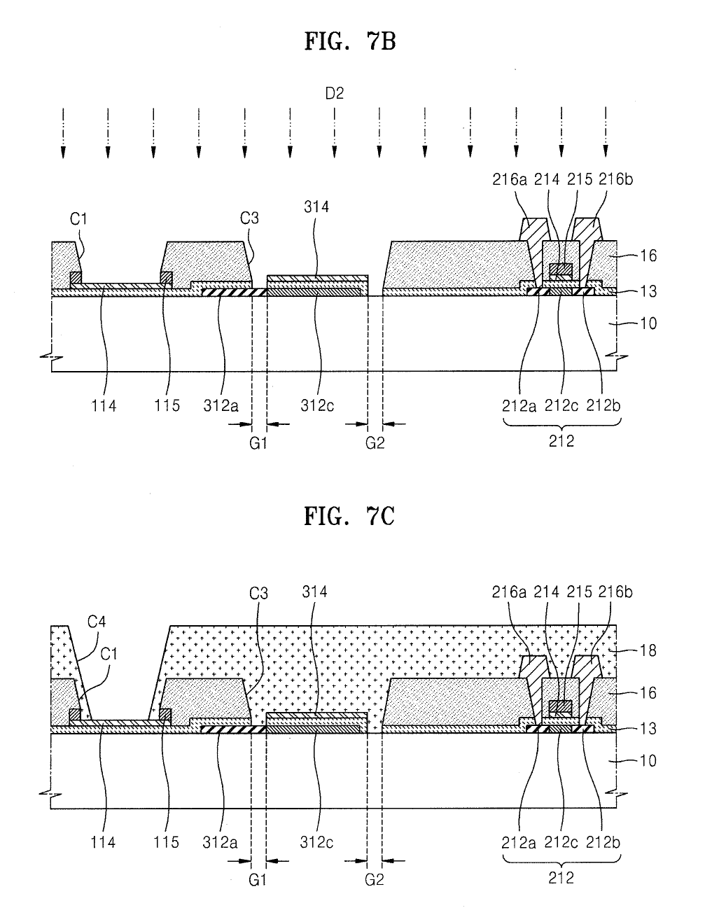

FIGS. 7A through 7C are cross-sectional views for describing a method of manufacturing an organic light-emitting display according to a second comparative example.

First and second mask processes of the organic light-emitting display according to the second comparative example are identical to those of the organic light-emitting display according to the first comparative example. Hereinafter, third through fifth mask processes are described with reference to FIGS. 7A through 7C.

Referring to FIG. 7A, the second insulation layer 16 is formed, and then the opening C1 exposing the pixel region, the opening C2 exposing parts of the source and drain regions 212a and 212b of the active layer 212, and the opening C3 exposing the upper electrodes 314 and 315 are formed in a third mask process. Here, the opening C3 is formed larger than the upper electrodes 314 and 315 so as to expose the entire upper electrodes 314 and 315. Since the first and second insulation layers 13 and 16 are etched together in the same mask process, a part of the first insulation layer 13 exposed through the opening C3 is removed in the capacitor region to form first and second portions G1 and G2 of a gap.

Referring to FIG. 7B, when a silicon-metal compound, such as silicide, is generated by contact of the second metal layer with the first connector 312a in the first portion G1 of the gap in the fourth mask process, and then remains without being completely removed, the lower and upper electrodes 312b and 317b may be short-circuited due to a leakage current. Thus, a dark spot may be generated in a corresponding pixel due to the short circuit.

Referring to FIG. 7C, the third insulation layer 18 is stacked on the result product of the fourth mask process, and then is patterned to form the opening C4 exposing the top of the pixel electrode 114.

Thus, according to the second comparative example, the lower and upper electrodes 312b and 317b may be short-circuited due to the leakage current by the silicon-metal compound remaining in the first portion G1 without being completely removed. A dart spot is generated in the corresponding pixel due to the short circuit, thereby deteriorating the quality of the organic light-emitting display device.

Various embodiments provide the following advantages.

First, by forming a bridge in a gap formed in an insulation layer outside a lower electrode of a capacitor, a wire connected to the lower electrode may be prevented from being short-circuited due to a stepped difference of the insulation layer.

Second, by forming a protection film in a gap between a lower electrode of a capacitor and a wire connected to the lower electrode, a leakage current is prevented from being generated between an upper electrode and the lower electrode due to a silicon-metal compound.

Third, signal transmission efficiency of a capacitor is improved as a phenomenon of ion impurities not doped between a lower electrode of the capacitor and a wire connected to the lower electrode is removed.

Fourth, an organic light-emitting display described above may be manufactured via six mask processes.

While the above embodiments have been described with reference to the accompanying drawings, it will be understood by those of ordinary skill in the art that various changes in form and details may be made therein without departing from the spirit and scope as defined by the following claims.

What is claimed is:

1. A thin-film transistor array substrate comprising:
a thin-film transistor comprising an active layer, a gate electrode, a source electrode, and a drain electrode;
a lower electrode of a capacitor formed of the same layer as the active layer;
an upper electrode of the capacitor formed on the lower electrode;
a first insulation layer formed between the lower and upper electrodes, and formed between the active layer and the gate electrode, wherein a gap is formed outside the lower electrode;
a second insulation layer formed on the first insulation layer and having the same etching surface as the first insulation layer in the gap;
a bridge formed of the same material as at least one of the source and drain electrodes, wherein the bridge at least partially fills the gap;
a pixel electrode formed of the same material as the upper electrode; and
a third insulation layer covering the source and drain electrodes, wherein an opening is defined in the third insulation layer, and wherein at least part of the pixel electrode is formed in the opening.

2. The thin-film transistor array substrate of claim 1, wherein the active layer and the lower electrode are formed of an ion impurity-doped semiconductor material.

3. The thin-film transistor array substrate of claim 1, wherein the upper electrode and the pixel electrode are formed of a transparent conductive material.

4. The thin-film transistor array substrate of claim 3, wherein the transparent conductive material comprises at least one selected from the group consisting of an indium tin oxide (ITO), an indium zinc oxide (IZO), a zinc oxide (ZnO), an indium oxide (In2O3), an indium gallium oxide (IGO), and an aluminum zinc oxide (AZO).

5. The thin-film transistor array substrate of claim 1, further comprising:
a first connector connected to the lower electrode; and
a second connector connected to the upper electrode,
wherein a first portion of the gap is formed between the lower electrode and the first connector, and wherein a second portion of the gap is formed in the first insulation layer formed outside the lower electrode.

6. The thin-film transistor array substrate of claim 5, wherein the bridge is formed in the second portion of the gap.

7. The thin-film transistor array substrate of claim 5, wherein the first connector is formed of the same material as the lower electrode.

8. The thin-film transistor array substrate of claim 5, wherein the second connector is formed of the same material as the upper electrode.

9. The thin-film transistor array substrate of claim 8, wherein the second connector is formed on and connected to the bridge formed in the second portion of the gap and the second insulation layer.

10. The thin-film transistor array substrate of claim 9, further comprising a wire formed of the same material as the source and drain electrodes between the second connector and the second insulation layer, wherein the wire directly contacts the second connector.

11. The thin-film transistor array substrate of claim 5, further comprising a protection film formed in the first portion of the gap.

12. The thin-film transistor array substrate of claim 11, wherein the protection film is formed of the same material as the source and drain electrodes.

13. The thin-film transistor array substrate of claim 11, wherein the protection film is formed of the same material as the upper electrode.

14. The thin-film transistor array substrate of claim 11, wherein the protection film is electrically insulated from the upper electrode.

15. The thin-film transistor array substrate of claim 1, wherein the third insulation layer contacts the upper electrode.

16. An organic light-emitting display comprising:
a thin-film transistor comprising an active layer, a gate electrode, a source electrode, and a drain electrode;
a lower electrode of a capacitor formed of the same layer as the active layer;
an upper electrode of the capacitor formed on the lower electrode;
a first insulation layer formed between the lower and upper electrodes, and formed between the active layer and the gate electrode, wherein a gap is formed outside the lower electrode;
a second insulation layer formed on the first insulation layer and having the same etching surface as the first insulation layer;
a bridge formed of the same material as the source and drain electrodes, wherein the bridge at least partially fills the gap;
a pixel electrode formed of the same material as the upper electrode;
a third insulation layer covering the source and drain electrodes, wherein an opening is defined in the third insulation layer, and wherein at least part of the pixel electrode is formed in the opening;
an organic light-emitting layer formed on the pixel electrode; and
a counter electrode formed on the organic light-emitting layer.

17. The organic light-emitting display of claim 16, wherein the counter electrode is a reflective electrode configured to reflect light emitted from the organic light-emitting layer.

18. The organic light-emitting display of claim 16, wherein the pixel electrode is formed of a transparent conductive material.

19. The organic light-emitting display of claim 18, wherein the pixel electrode further comprises a semi-transmission layer formed of a semi-transmission material.

20. A method of manufacturing a thin-film transistor array substrate, the method comprising:
forming a semiconductor layer on a substrate and forming an active layer of a thin-film transistor and a lower electrode of a capacitor by patterning the semiconductor layer;
forming a first insulation layer, forming a first metal layer on the first insulation layer, and forming an etch stop layer corresponding to the lower electrode and a gate electrode corresponding to a portion of the active layer based on patterning the first metal layer;
forming a second insulation layer, and etching the first and second insulation layers such that a gap exposing the etch stop layer and an opening exposing a portion of the active layer are formed;
forming a second metal layer, and forming a bridge filing a portion of the gap and source and drain electrodes substantially filling the opening of the active layer based on patterning the second metal layer;
forming a third metal layer, and forming a pixel electrode and an upper electrode of the capacitor based on patterning the third metal layer; and
forming a third insulation layer, and forming an opening which exposes the pixel electrode.

21. The method of claim 20, further comprising doping an ion impurity after forming the etch stop layer.

22. The method of claim 20, wherein the etch stop layer is removed while forming the second insulation layer and etching the first and second insulation layers.

23. The method of claim 20, further comprising doping an ion impurity after forming the source and drain electrodes.

24. The method of claim 20, further comprising, while forming the semiconductor layer, the active layer and the lower electrode, forming a first connector connected to the lower electrode based on patterning the semiconductor layer.

25. The method of claim 24, further comprising, while forming the second insulation layer and etching the first and second insulation layers, forming i) a first portion of the gap between the lower electrode and the first connector, and ii) a second portion of the gap in the first insulation layer which is formed outside the lower electrode.

26. The method of claim 25, wherein the bridge is formed in the second portion of the gap while forming the second metal layer, the bridge, and the source and drain electrodes.

27. The method of claim 26, further comprising, while forming the third metal layer, the pixel electrode and the upper electrode, forming a second connector connected to the upper electrode based on patterning the third metal layer, wherein the second connector is formed on the bridge.

28. The method of claim 23, further comprising, while forming the second metal layer, the bridge, and the source and drain electrodes, forming a protection film in the first portion of the gap based on the second metal layer.

29. The method of claim 23, further comprising, while forming the third metal layer, the pixel electrode and the upper electrode, forming a protection film in the first portion of the gap based on the third metal layer.
